(19) United States
(12) Patent Application Publication
(10) Pub. No.: US 2015/0145124 A1
(43) Pub. Date: May 28, 2015

(54) SEMICONDUCTOR CHIPS WITH THROUGH-SILICON VIAS, AND SEMICONDUCTOR PACKAGES INCLUDING THE SAME

(71) Applicant: Samsung Electronics Co., Ltd., Suwon-si (KR)

(72) Inventors: SinWoo KANG, Suwon-si (KR); Sungdong CHO, Hwaseong-si (KR)

(21) Appl. No.: 14/327,674

(22) Filed: Jul. 10, 2014

(30) Foreign Application Priority Data
Nov. 26, 2013 (KR) 10-2013-0144657

(51) Int. Cl. H01L 23/48; H01L 23/00

(52) U.S. Cl. CPC H01L 23/481; H01L 24/13; H01L 24/05; H01L 2224/05; H01L 2224/13
USPC 257/737

(57) ABSTRACT

Provided is a semiconductor device with through-silicon vias. The device includes a substrate including a lower semiconductor layer, a buried insulating layer, and an upper semiconductor layer, electronic devices on the upper semiconductor layer, a vertical electrode structure including a vertical electrode penetrating the substrate, and an electrode separation pattern surrounding the vertical electrode structure in a plan view and penetrating the upper semiconductor layer to directly contact the buried insulating layer.

### CROSS-REFERENCE TO RELATED APPLICATION

This U.S. non-provisional patent application claims priority under 35 U.S.C. §119 to Korean Patent Application No. 10-2013-0144657, filed on Nov. 26, 2013, in the Korean Intellectual Property Office, the entire contents of which are hereby incorporated herein by reference.

### BACKGROUND

The present disclosure relates to semiconductor devices and semiconductor packages including semiconductor devices. A vertical interconnection structure using through-silicon vias (TSVs) has been suggested. The use of the TSVs may make it possible to reduce a length of an interconnection line connecting semiconductor chips, and consequently, to improve performance of a three-dimensional package. Furthermore, because each of the TSVs may be formed to have a width of several micrometers, it may be possible to form thousands of the TSVs in each semiconductor chip. For example, TSV-based wide Input/Output (I/O) technologies have been recently suggested to realize a bandwidth of 100 Gigabits (Gbits)/second or higher.

### SUMMARY

Example embodiments of the inventive concept provide fabricating methods capable of preventing internal circuits of a semiconductor chip from being damaged by a process of forming through-silicon vias.

Other example embodiments of the inventive concept provide semiconductor chips, which are configured to prevent internal circuits therein from being damaged by a process of forming through-silicon vias, and semiconductor packages including the same.

According to example embodiments of the inventive concept, a semiconductor device may include a substrate including a lower semiconductor layer, a buried insulating layer, and an upper semiconductor layer, electronic devices integrated on the upper semiconductor layer, a vertical electrode structure including vertical electrodes penetrating the substrate, and an electrode separation pattern provided to surround the vertical electrode structure in a plan view and to penetrate the upper semiconductor layer to be in direct contact with the buried insulating layer in a vertical section.

In example embodiments, the electrode separation pattern may have a thickness larger than that of the upper semiconductor layer.

In example embodiments, the electronic devices may be separated from both of the lower semiconductor layer and the vertical electrode structure by the buried insulating layer and the electrode separation pattern.

In example embodiments, the device may further include a device isolation pattern defining active regions, on which the electronic devices is be provided.

In example embodiments, the device isolation pattern may be provided to penetrate the upper semiconductor layer and be in direct contact with the buried insulating layer.

In example embodiments, the device isolation pattern may have a thickness smaller than that of the upper semiconductor layer.

In example embodiments, the electrode separation pattern may be disposed spaced apart from the device isolation pattern.

In example embodiments, the device isolation pattern may be disposed around the vertical electrode structure, and the electrode separation pattern may be disposed to penetrate the device isolation pattern.

In example embodiments, the electrode separation pattern may include a plurality of island-shaped patterns, each of which surrounds a corresponding one of the vertical electrodes.

In example embodiments, the vertical electrodes may be disposed in a bump region of the substrate, and the electrode separation pattern may include at least one closed-loop-shaped pattern surrounding the bump region.

In example embodiments, the electrode separation pattern may be formed of at least one of a silicon oxide layer, a silicon nitride layer, or a silicon oxynitride layer.

In example embodiments, the device may further include an interlayer insulating layer disposed on the upper semiconductor layer. Here, the electrode separation pattern may be disposed between the buried insulating layer and the interlayer insulating layer.

According to example embodiments of the inventive concept, a semiconductor package may include a package substrate and a plurality of semiconductor chips provided on the package substrate. Here, at least one of the plurality of semiconductor chips is a chip of a first type including a substrate with a lower semiconductor layer, a buried insulating layer, and an upper semiconductor layer, electronic devices integrated on the upper semiconductor layer, a vertical electrode structure including vertical electrodes penetrating the substrate, and an electrode separation pattern provided to surround the vertical electrode structure in a plan view and to be in direct contact with the buried insulating layer through the upper semiconductor layer in a vertical section.

In example embodiments, the plurality of semiconductor chips may include a plurality of memory chips, which are sequentially stacked on the package substrate to form a memory-chip stacking structure, and at least one of the memory chips is the chip of the first type.

In example embodiments, the plurality of semiconductor chips may further include at least one logic chip provided between the plurality of memory chips and the package substrate or provided on the package substrate with the plurality of memory chips interposed therebetween, and at least one logic chip is the chip of the first type.

In example embodiments, the vertical electrodes may be disposed in a bump region of the substrate, and the electrode separation pattern comprises at least one closed-loop-shaped pattern surrounding the bump region.

In example embodiments, the vertical electrodes may be disposed in a bump region of the substrate, the electrode separation pattern may include a plurality of island-shaped patterns, each of which surrounds a corresponding one of the vertical electrodes.

In example embodiments, the chip of the first type may further include a device isolation pattern defining active regions, on which the electronic devices are provided. Here, the electrode separation pattern has a thickness that is greater than that of the upper semiconductor layer, and the device isolation pattern has a thickness that is substantially equal to or smaller than that of the electrode separation pattern.

According to example embodiments of the inventive concept, a semiconductor device may include a substrate including a lower semiconductor layer, a buried insulating layer, and an upper semiconductor layer, a device isolation pattern provided in the upper semiconductor layer to define active regions, electronic devices integrated on the active regions, vertical electrodes penetrating the substrate, and an electrode separation pattern provided to surround the vertical electrodes in a plan view and to be in direct contact with the buried insulating layer through the upper semiconductor layer in a vertical section. Here, a thickness of the electrode separation pattern is greater than that of the upper semiconductor layer, and a thickness of the device isolation pattern is substantially equal to or smaller than that of the electrode separation pattern.

In example embodiments, the electronic devices are electrically isolated from all of the vertical electrodes by the buried insulating layer and the electrode separation pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a portion of semiconductor device according to example embodiments of the inventive concept.

FIG. 2 is a sectional view illustrating an example of a vertical structure of an electrode separation pattern, according to example embodiments of the inventive concept.

FIGS. 3 through 7 are perspective views illustrating some examples of possible horizontal dispositions of the electrode separation pattern.

FIG. 8 is a plan view schematically illustrating a semiconductor device according to example embodiments of the inventive concept.

FIGS. 9 through 14 are plan views enlarging a portion of FIG. 8.

FIGS. 15 through 17 are sectional views illustrating some possible examples of a semiconductor package including a semiconductor device according to the inventive concept.

FIG. 18 is a flow chart illustrating a method of fabricating a semiconductor device according to example embodiments of the inventive concept.

FIGS. 19 through 27 are sectional views illustrating a method of fabricating a semiconductor device according to example embodiments of the inventive concept.

FIG. 28 is a flow chart illustrating a method of fabricating a semiconductor device according to other example embodiments of the inventive concept.

FIGS. 29 through 33 are sectional views illustrating a method of fabricating a semiconductor device according to other example embodiments of the inventive concept.

FIG. 34 is a flow chart illustrating a method of fabricating a semiconductor device according to still other example embodiments of the inventive concept.

FIGS. 35 through 38 are sectional views illustrating a method of fabricating a semiconductor device according to still other example embodiments of the inventive concept.

FIG. 39 is a flow chart illustrating a method of fabricating a semiconductor device according to even other example embodiments of the inventive concept.

FIGS. 40 through 42 are sectional views illustrating a method of fabricating a semiconductor device according to even other example embodiments of the inventive concept.

FIGS. 43 and 44 are block diagrams schematically illustrating electronic devices including a semiconductor device according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

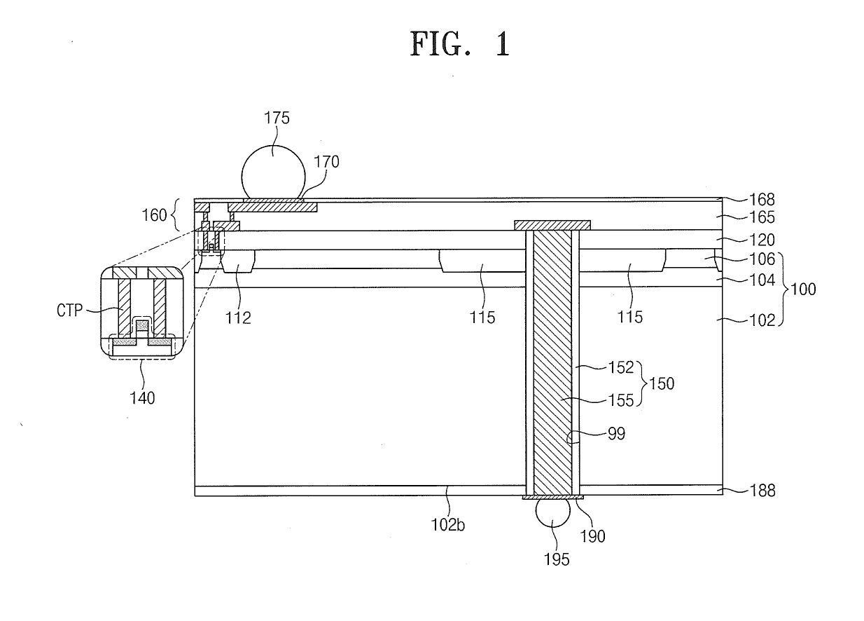

FIG. 1 is a sectional view illustrating a portion of semiconductor device according to example embodiments of the inventive concept.

Referring to FIG. 1, a semiconductor device may be provided to include a substrate 100 and a vertical electrode structure 150 penetrating the substrate 100. The substrate 100 may include an insulating layer and a semiconductor layer provided thereon. For example, the substrate 100 may include a lower semiconductor layer 102, a buried insulating layer 104, and an upper semiconductor layer 106. In example embodiments, the substrate 100 may be a silicon-on-insulator (SOI) wafer.

The vertical electrode structure 150 may be provided in a plurality of vertical electrode holes 99 wholly or partially penetrating the substrate 100. For example, the vertical electrode structure 150 may include insulating liners 152 covering inner side surfaces of the vertical electrode holes 99 and a plurality of vertical electrodes 155, each of which is provided to fill a corresponding one of the vertical electrode holes 99 covered with the insulating liners 152. The insulating liners 152 may be formed of or include at least one of silicon oxide, silicon nitride, or silicon oxynitride. The vertical electrodes 155 may be formed of or include at least one of copper, tungsten, or metal nitrides.

The semiconductor device may further include electronic devices 140 (for example, transistors, capacitors, diodes, or resistors) formed on (e.g., formed on top of or at least partially within) the upper semiconductor layer 106, and an interconnection structure 160 connecting the electronic devices 140 to each other. The electronic devices 140 may be electrically connected to each other via the interconnection structure 160 to constitute an integrated circuit. In example embodiments, the integrated circuit may be configured in such a way that the semiconductor device serves as a volatile memory device or a nonvolatile memory device. Alternatively, the integrated circuit may be configured in such a way that the semiconductor device serves as a central processing unit (CPU), a graphic processing unit (GPU), a sensor, a communication chip, a controller, or an interposer with electronic devices, but example embodiments of the inventive concept may not be limited thereto.

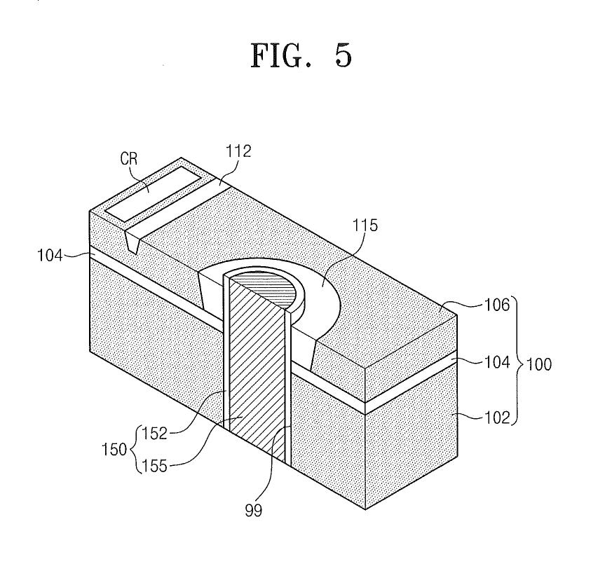

In example embodiments, the semiconductor device may include an insulating separation structure formed in the upper semiconductor layer 106. For example, the insulating separation structure may include at least one device isolation pattern 112 defining active regions, on which the electronic devices 14Q will be formed, and at least one electrode separation pattern 115 interposed between the electronic devices 140 and the vertical electrode structure 150. As will be described with reference to FIGS. 3 through 7, the device isolation pattern 112 and the electrode separation pattern 115 may be formed by the same process or by different processes to have the same depth or different depths to each other.

When viewed in a plan view, the electrode separation pattern 115 may be formed to enclose the vertical electrode structure 150. In example embodiments, the vertical electrode structure 150 may be formed to penetrate the electrode separation pattern 115, and in this case, the electrode separation pattern 115 may be in direct contact with the vertical electrode structure 150 and enclose the vertical electrode structure 150. In other example embodiments, the electrode separation pattern 115 may be formed spaced apart from the vertical electrode structure 150 to enclose the vertical electrode structure 150. Since the vertical electrode structure 150 is enclosed by the electrode separation pattern 115, the vertical electrode structure 150 may be spatially and electrically separated from the electronic devices 140, when viewed in a plan view.

When viewed in a vertical section, the electronic devices 140 may be spatially and electrically separated from the lower semiconductor layer 102 by the buried insulating layer 104. Accordingly, the electronic devices 140 and the vertical electrode structure 150 may be separated from each other in both of horizontal and vertical directions. In other words, although a semiconductor material (for example, the lower semiconductor layer 102 of FIG. 1) may be in direct contact with the vertical electrode structure 150, the semiconductor material can be electrically disconnected from the electronic devices 140, by virtue of the buried insulating layer 104 and the electrode separation pattern 115.

Due to such a disconnection, the electronic devices 140 can be free from several bad influences resulting in the process of forming the vertical electrode structure 150. For example, due to the presence of the buried insulating layer 104 and the electrode separation pattern 115, it is possible to prevent charged particles, which may be produced in the process of forming the vertical electrode holes 99, from flowing into the electronic devices 140 or a portion of the upper semiconductor layer 106 adjacent to the electronic devices 140.

The semiconductor device may further include an interlayer insulating layer 120 and an inter-metal insulating layer 165 sequentially provided on the upper semiconductor layer 106. Each of the interlayer and inter-metal insulating layers 120 and 165 may include at least one of silicon oxide, silicon nitride, silicon oxynitride, or low-k dielectric layers. Contact plugs CTP may be provided in the interlayer insulating layer 120 and be connected to the electronic devices 140. The interconnection structure 160 may include a plurality of metal layers provided in the inter-metal insulating layer 165 and may be electrically connected to the electronic devices 140 via the contact plugs CTP. As illustrated in FIG. 1, at least one of the metal layers constituting the interconnection structure 160 may be in direct contact with the vertical electrode 155.

An upper protection layer 168 may be provided to cover a top surface of the inter-metal insulating layer 165, and a lower protection layer 188 may be provided to cover a bottom surface 102b of the lower semiconductor layer 102. The upper protection layer 168 may be formed to expose a portion of the interconnection structure 160, and the lower protection layer 188 may be formed to expose a portion of the vertical electrode 155. An upper connection terminal 175 may be provided on the interconnection layer 160 exposed by upper protection layer 168 and a lower connection terminal 195 may be provided on the vertical electrode 155 exposed by the lower protection layer 188. The upper connection terminal 175 may be connected to the exposed portion of the interconnection structure 160 via an upper under-bump-metallurgy UBM 170, and the lower connection terminal 195 may be connected to the exposed portion of the vertical electrode 155 via a lower UBM 190.

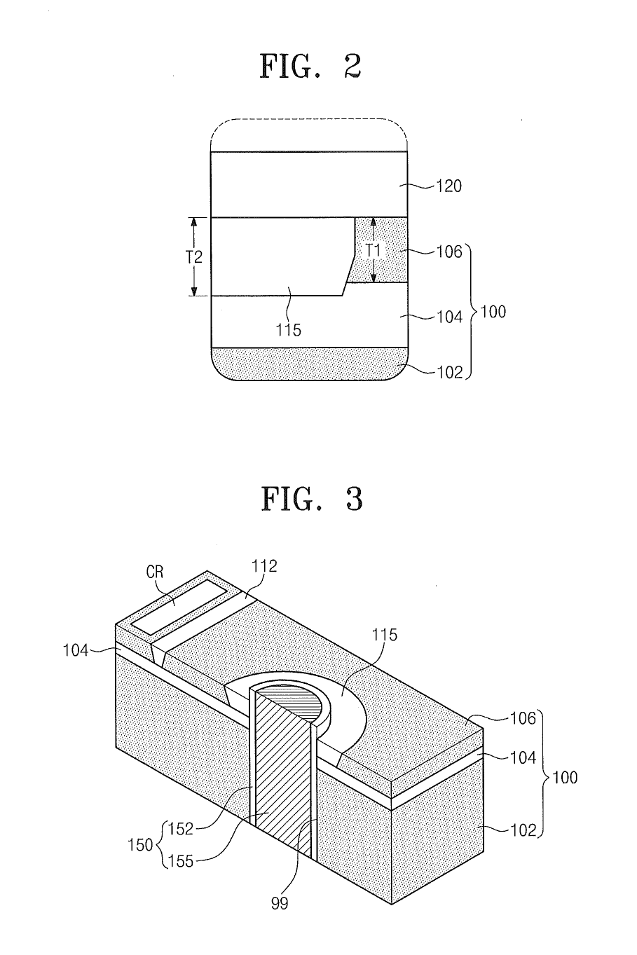

FIG. 2 is a sectional view illustrating an example of a vertical structure of an electrode separation pattern, according to example embodiments of the inventive concept.

Referring to FIG. 2, the electrode separation pattern 115 may be formed to penetrate the upper semiconductor layer 106 and thereby be in direct contact with the buried insulating layer 104. In example embodiments, the electrode separation pattern 115 may be formed to have a thickness T2 that is larger than a thickness T1 of the upper semiconductor layer 106. For example, the electrode separation pattern 115 may include a portion inserted into a top portion of the buried insulating layer 104. In this case, it is possible to prevent/impede the upper semiconductor layer 106 from remaining between the electrode separation pattern 115 and the buried insulating layer 104. This makes it possible to improve an electrical insulating property between the vertical electrode structure 150 and the electronic devices 140.

FIGS. 3 through 7 are perspective views illustrating some examples of possible horizontal dispositions of the electrode separation pattern.

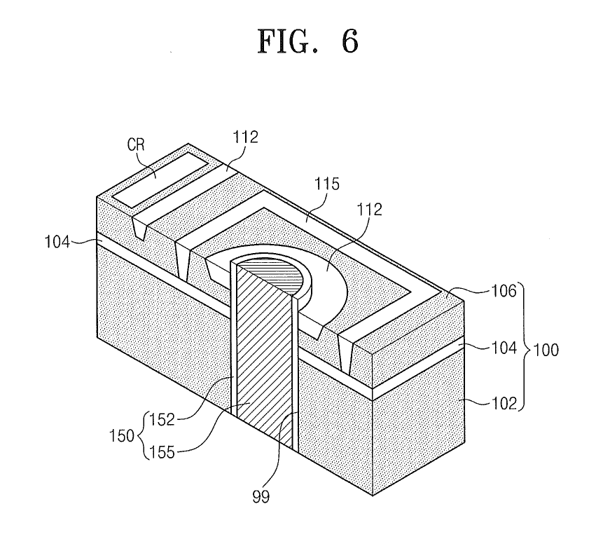

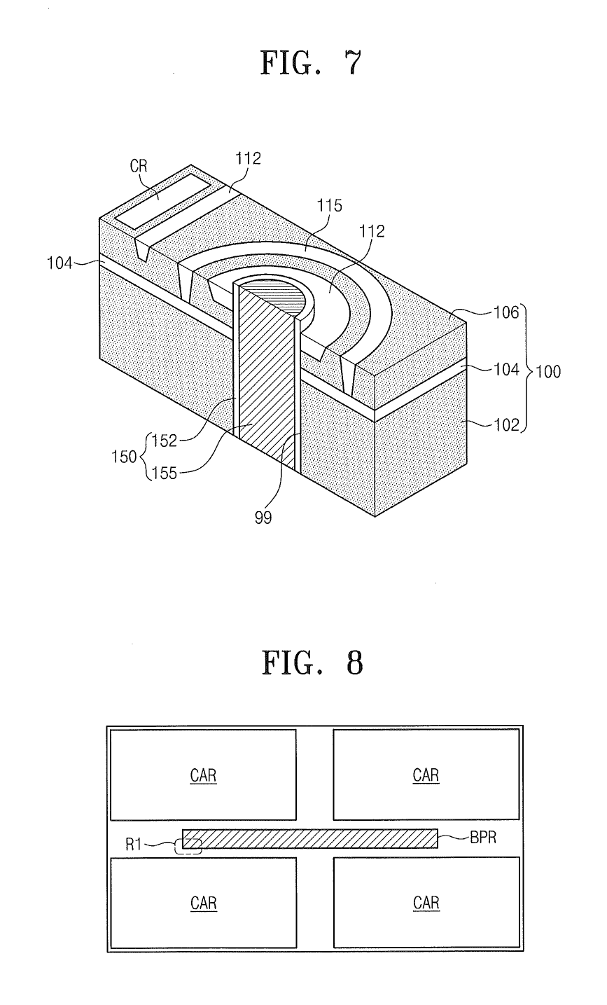

The electrode separation pattern 115 may be provided between a circuit region CR provided with the electronic devices 140 and the vertical electrode structure 150. For example, the vertical electrode structure 150 may be formed to penetrate the electrode separation pattern 115, as shown in FIGS. 3 through 5. Alternatively, the vertical electrode structure 150 may be spaced apart from the electrode separation pattern 115 and be enclosed by the electrode separation pattern 115, as shown in FIGS. 6 and 7.

In terms of a vertical depth, as shown in FIG. 3, the electrode separation pattern 115 may be formed to have substantially the same depth as that of the device isolation pattern 112. For example, the electrode separation pattern 115 and the device isolation pattern 112 may be formed using the same patterning process, and in this case, they are substantially the same as each other in terms of material and depth.

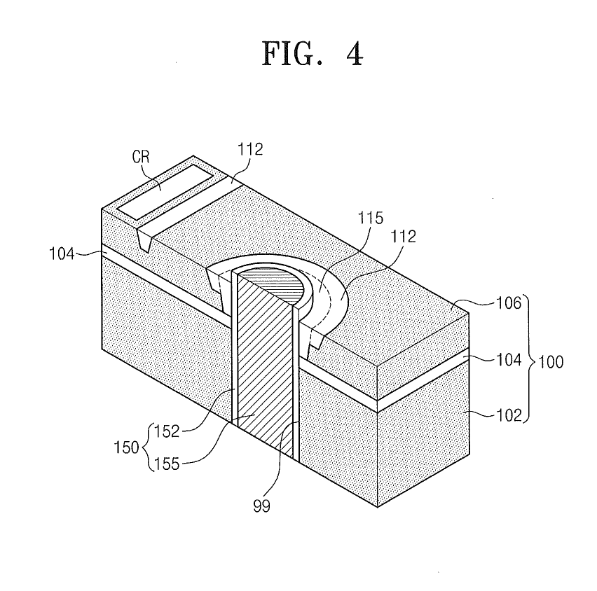

Alternatively, as shown in FIGS. 4 through 7, a depth of the electrode separation pattern 115 may be different from that of the device isolation pattern 112. For example, the electrode separation pattern 115 and the device isolation pattern 112 may be formed using different patterning processes. In example embodiments, the formation of the electrode separation pattern 115 may follow the formation of the device isolation pattern 112, but in other example embodiments, the formation of the electrode separation pattern 115 may be followed by the formation of the device isolation pattern 112.

As shown in FIGS. 4 through 7, the device isolation pattern 112 may be formed in an upper region of the upper semiconductor layer 106 to have a bottom surface spaced apart from the buried insulating layer 104. Alternatively, the electrode separation pattern 115 may be formed to penetrate the upper semiconductor layer 106 and thereby to be in direct contact with the buried insulating layer 104. For example, as shown in FIG. 2, the electrode separation pattern 115 may be formed to include a portion inserted into the buried insulating layer 104.

In the case where, as described above, the electrode separation pattern 115 and the device isolation pattern 112 are formed using different patterning processes, the electrode separation pattern 115 may be formed to be overlapped with the device isolation pattern 112. For example, as shown in FIG. 4, the electrode separation pattern 115 may be formed to penetrate the device isolation pattern 112, and the vertical electrode structure 150 may be formed to penetrate both of the device isolation pattern 112 and the electrode separation pattern 115.

In example embodiments, as shown in FIGS. 6 and 7, the device isolation pattern 112 may include two spaced-apart portions surrounding the vertical electrode structure 150 and the circuit region CR, respectively, and the electrode separation pattern 115 may be provided between such two spaced-apart portions of the device isolation pattern 112. In other example embodiments, when viewed in a plan view, the electrode separation pattern 115 may include a plurality of patterns forming several closed loops. For example, the device isolation pattern 112, which is disposed adjacent to the vertical electrode structure 150 in FIGS. 6 and 7, may be modified to have substantially the same structure as that of the electrode separation pattern 115 described with reference to FIG. 2.

So far, planar disposition of the electrode separation pattern 115 relative to one vertical electrode 155 has been described. Hereinafter, planar disposition of the electrode separation pattern 115 relative to the vertical electrode structure 150 with the plurality of vertical electrodes 155 will be described in more detail with reference to FIGS. 8 through 14.

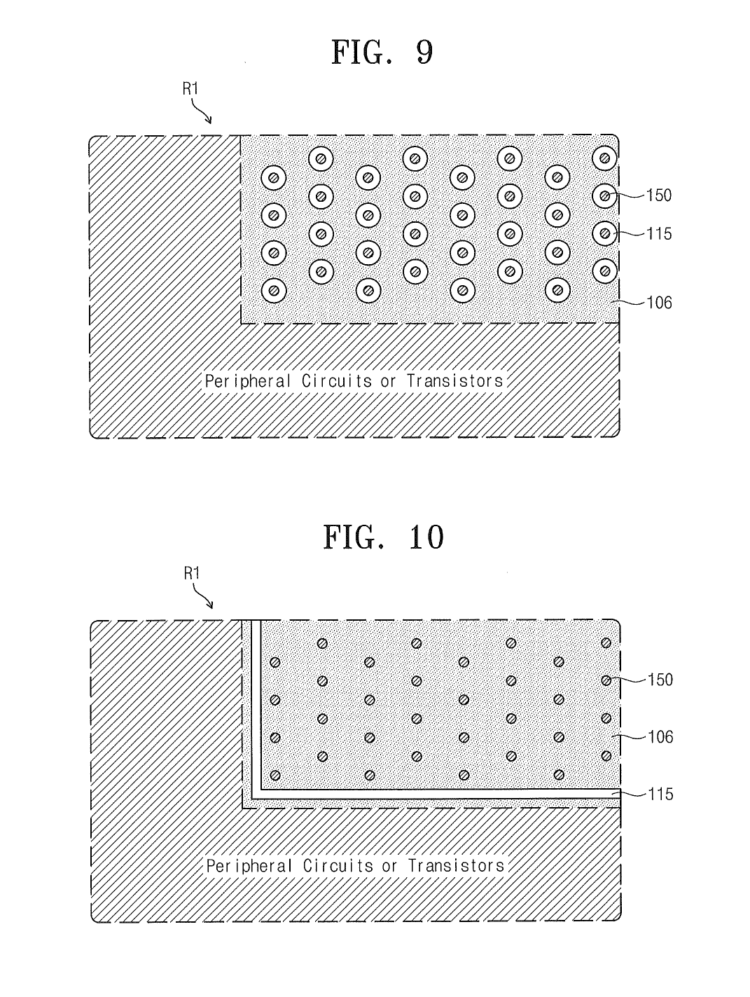

FIG. 8 is a plan view schematically illustrating a semiconductor device according to example embodiments of the inventive concept, and FIGS. 9 through 14 are plan views enlarging a portion R1 of FIG. 8.

In example embodiments, a semiconductor device may include a plurality of cell array regions CAR and at least one bump region BPR disposed between or around the cell array regions CAR. The cell array regions CAR may be configured to include two- or three-dimensional memory cells, which are integrated on the substrate 100. In other words, the semiconductor device according to the present embodiment may serve as a memory device, but the semiconductor device may not be limited to the memory device, which is described to explain exemplarily the inventive concept.

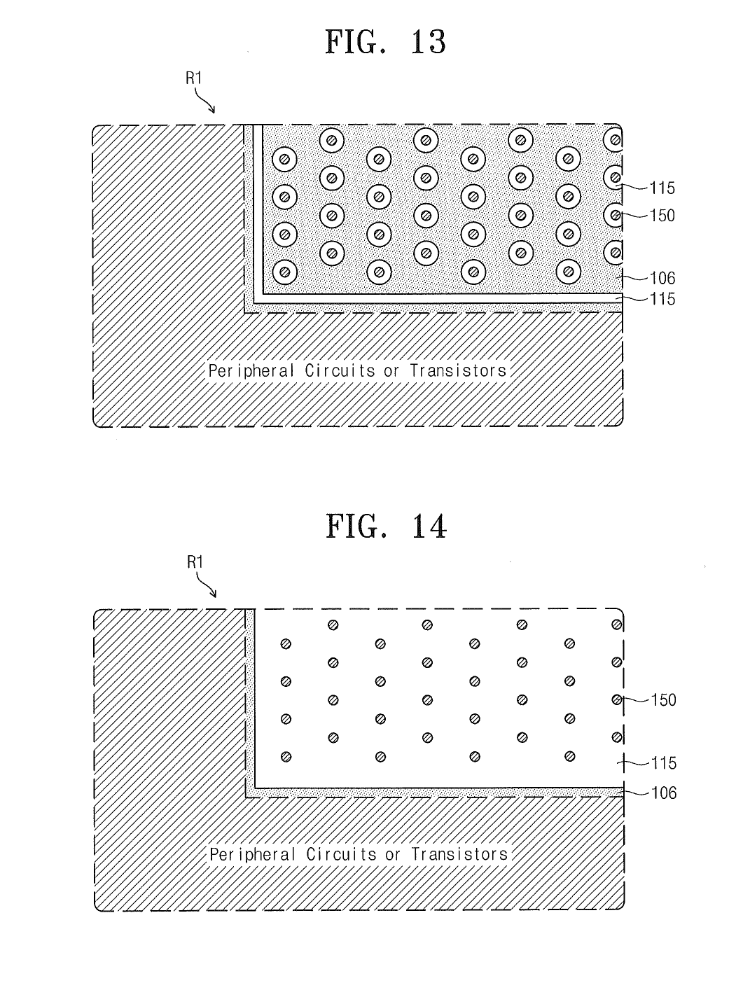

As shown in FIGS. 9 through 14, the vertical electrode structure 150 including a plurality of vertical electrodes 155 may be provided in the bump region BPR. In example embodiments, as shown in FIGS. 9 and 13, the insulating separation structure may include a plurality of electrode separation patterns 115, which are formed to enclose the vertical electrodes 155, respectively. For example, each of the electrode separation patterns 115 may be formed to have an island shape, and each of the vertical electrodes 155 may be formed to penetrate a corresponding one of the electrode separation patterns 115.

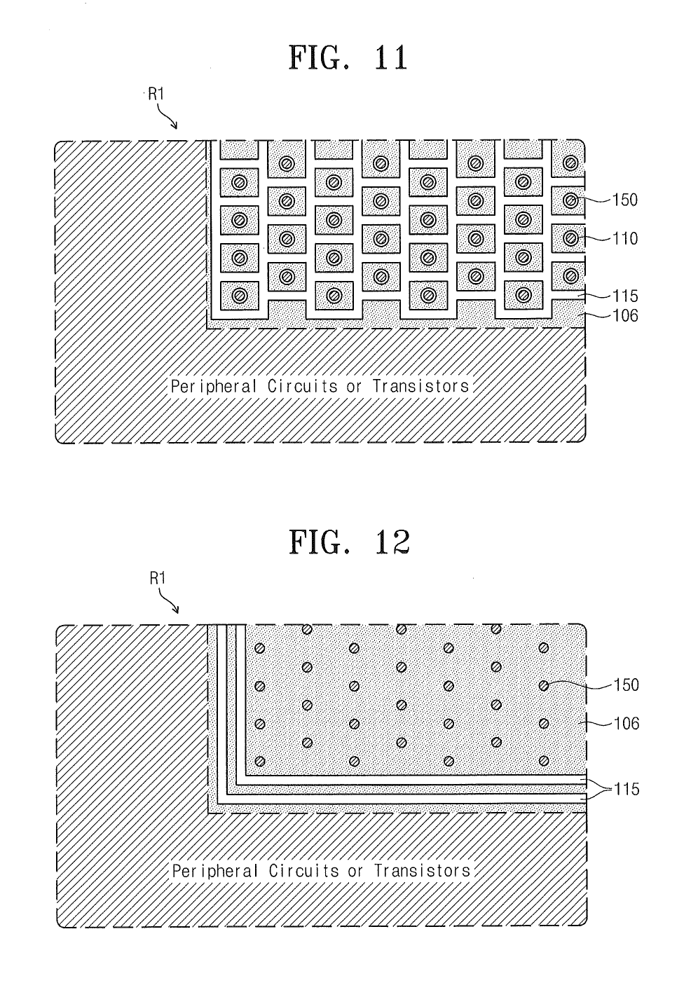

In other example embodiments, as shown in FIGS. 11 and 14, the insulating separation structure may include at least one electrode separation pattern 115 enclosing the plurality of vertical electrodes 155. For example, as shown in FIG. 11, the electrode separation pattern 115 may be formed to have a mesh-shaped structure, which is spaced apart from each or at least one of the vertical electrodes 155. Alternatively, as shown in FIG. 14, the electrode separation pattern 115 may be provided in the form of a single body that is in contact with and forms a perimeter around (e.g., surrounds) the vertical electrode structure 150.

In still other example embodiments, as shown in FIGS. 10 through 13, the insulating separation structure may include at least one electrode separation pattern 115, which is shaped like a closed loop and is spaced apart from the vertical electrodes 155 to surround the bump region BPR. For example, as shown in FIG. 11, the electrode separation pattern 115 may be provided to have a mesh-shaped structure, or as shown in FIG. 12, a plurality of the electrode separation patterns 115 may be provided around the bump region BPR to form multiple closed loops.

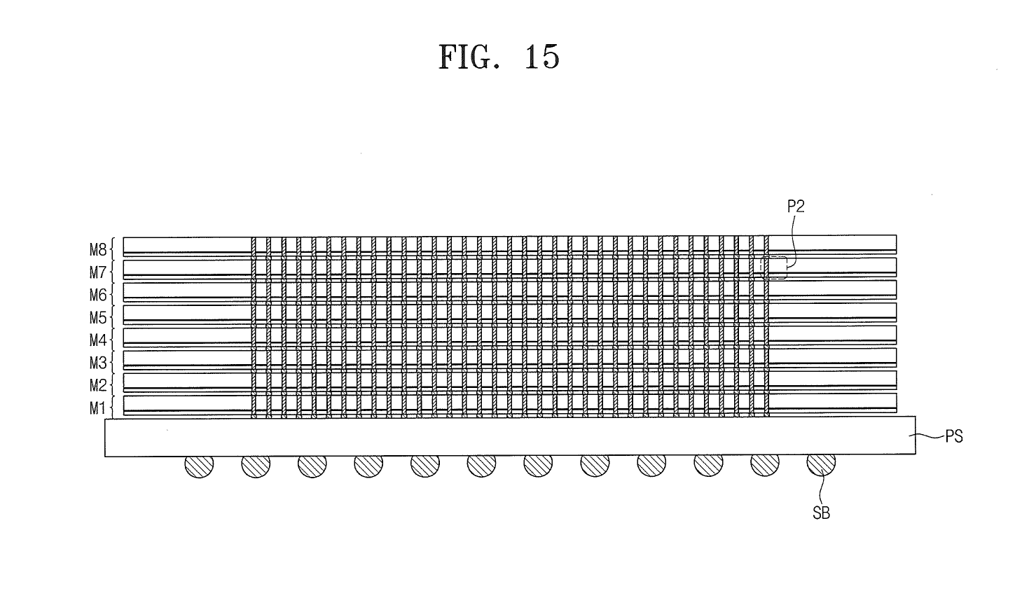

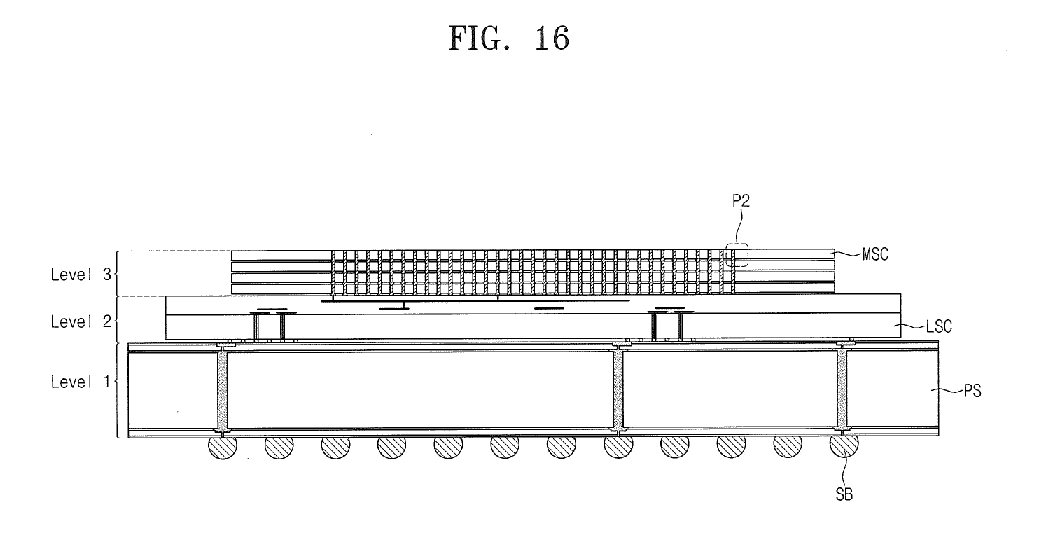

So far, a chip-level semiconductor device (hereinafter, semiconductor chip) has been described with reference to FIGS. 1 through 14. Hereinafter, some possible examples of a package-level semiconductor device including a plurality of semiconductor chips (hereinafter, semiconductor package) will be briefly described with reference to FIGS. 15 through 17.

Referring to FIG. 15, in example embodiments, a semiconductor package may include a package substrate PS and a plurality of memory semiconductor chips M1-M8 sequentially stacked on the package substrate PS. In other words, the semiconductor package according to the present embodiments may be configured to have a memory-chip stacking structure. Each or at least one of the memory semiconductor chips M1-M8 may be configured to have substantially the same technical features as one of the semiconductor chips described with reference to FIGS. 1 through 14. For example, at least one of the memory semiconductor chips M1-M8 may include a portion P2, which is configured to include the vertical electrode structure 150 and the insulating separation structure described with reference to FIG. 1. The memory semiconductor chips M1-M8 may be attached or connected to other electronic device via connection terminals SB (for example, solder balls) provided on a bottom surface of the package substrate PS.

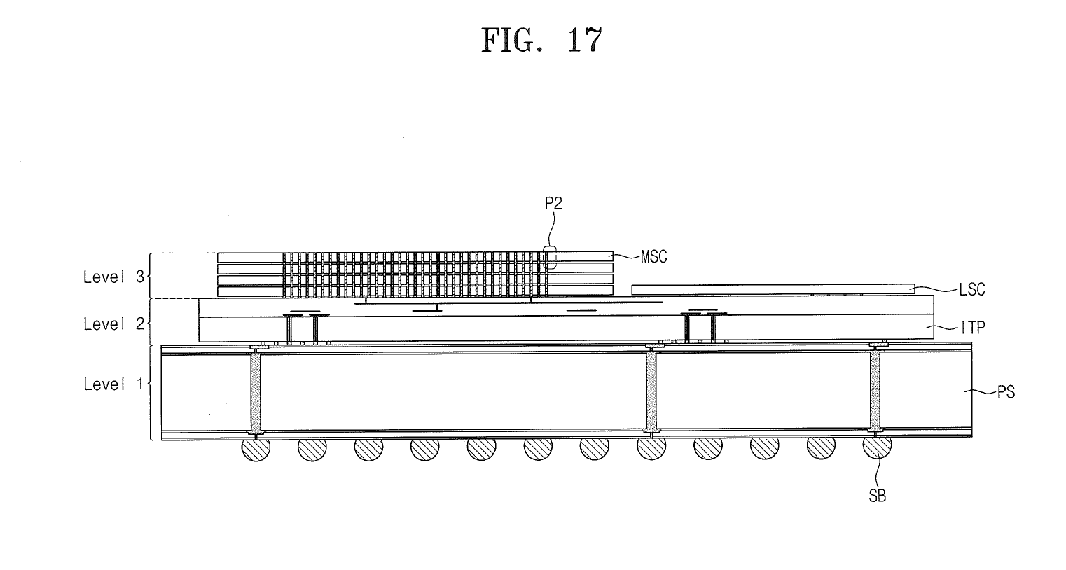

Referring to FIGS. 16 and 17, a semiconductor package may include the package substrate PS and a plurality of semiconductor chips sequentially stacked on the package substrate PS. For example, the semiconductor chips may include at least one logic semiconductor chip LSC and at least one memory semiconductor chip MSC. As shown in FIG. 16, the logic and memory semiconductor chips (LSC and MSC) may be vertically stacked at different levels (e.g., Level 2 and Level 3). In some embodiments, the memory semiconductor chips MSC may be stacked on the logic semiconductor chip LSC, but a stacking order of them may be changed. Alternatively, as shown in FIG. 17, the logic and memory semiconductor chips LSC and MSC may be horizontally provided on, for example, an active or passive interposer ITP including silicon through vias.

The memory semiconductor chip MSC may be configured to have substantially the same technical features as one of the semiconductor chips described with reference to FIGS. 1 through 14. For example, the memory semiconductor chip MSC may include a portion P2, which is configured to include the vertical electrode structure 150 and the insulating separation structure described with reference to FIG. 1. Furthermore, the logic semiconductor chip LSC may also be configured to have substantially the same technical features as one of the semiconductor chips described with reference to FIGS. 1 through 14. In other words, the logic semiconductor chip LSC may also be configured to include the vertical electrode structure 150 and the insulating separation structure described with reference to FIG. 1. In the meantime, the memory semiconductor chip has been described with reference to FIGS. 1 through 14, but the logic semiconductor chip LSC may be configured to have substantially the same technical features as those described with reference to FIGS. 1 through 14. According to, embodiments, in which the logic semiconductor chip LSC is configured to have such technical features, will not be described in much further detail, for the sake of simplicity.

The memory semiconductor chip(s) M1-M8 or MSC may be one of volatile memory devices (for example, DRAM or SRAM) or nonvolatile memory devices (for example, electrically-erasable programmable read-only memory (EEPROM), FLASH memory, magnetic RAM (MRAM), spin-transfer torque MRAM (STT-MRAM), conductive bridging RAM (CBRAM), ferroelectric RAM (FeRAM), phase-changeable RAM (PRAM), resistive memory (ReRAM), nanotube RRAM, polymer RAM (PoRAM), nano floating gate memory (NFGM), holographic memory, molecular electronics memory device, or insulator resistance change memory).

The logic semiconductor chip LSC may be a central processing unit (CPU), a graphic processing unit (GPU), a sensor, a communication chip, a controller, or an interposer with electronic devices, but example embodiments of the inventive concept may not be limited thereto.

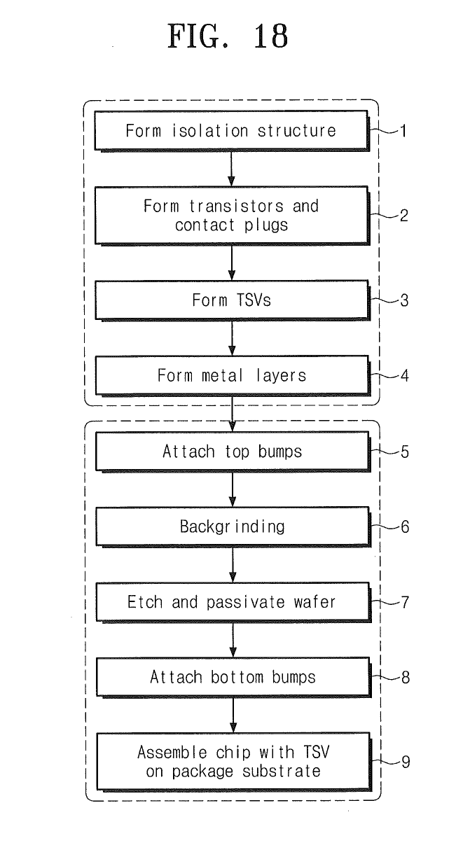

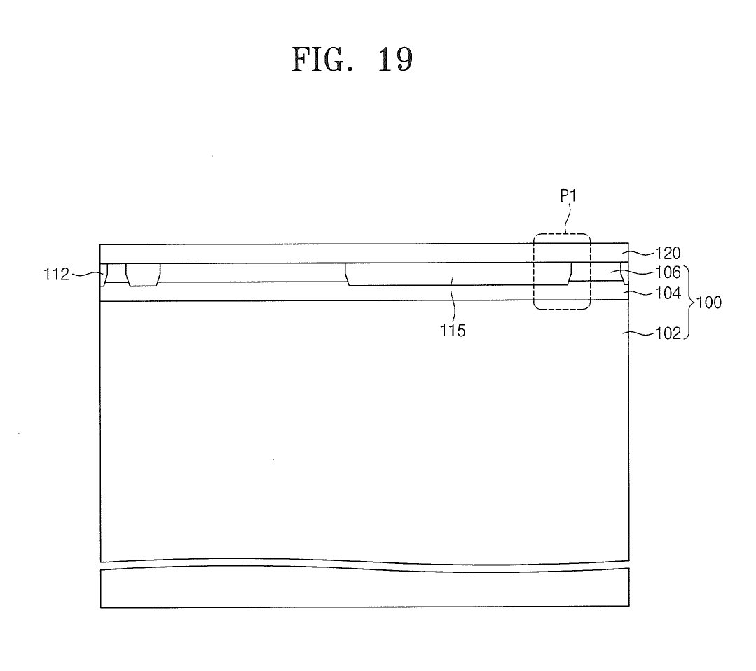

FIG. 18 is a flow chart illustrating a method of fabricating a semiconductor device according to example embodiments of the inventive concept, and FIGS. 19 through 27 are sectional views illustrating a method of fabricating a semiconductor device according to example embodiments of the inventive concept.

Referring to FIGS. 18 and 19, an insulating separation structure may be formed on a substrate 100 (in Block 1). The substrate 100 may include a semiconductor layer provided on an insulating layer. For example, the substrate 100 may include a lower semiconductor layer 102, a buried insulating layer 104, and an upper semiconductor layer 106. In example embodiments, the substrate 100 may be a silicon-on-insulator (SOI) wafer.

The insulating separation structure may include, for example, at least one device isolation pattern 112 defining active regions, on which the electronic devices 140 will be formed, and at least one electrode separation pattern 115 interposed between the electronic devices 140 and the vertical electrode structure 150. The electronic devices 140 may include a transistor, a capacitor, a diode, or a resistor. The electrode separation pattern 115 may be formed to penetrate the upper semiconductor layer 106 and thereby in direct contact with the buried insulating layer 104. In example embodiments, the electrode separation pattern 115 may be formed to have a thickness T2 larger than a thickness T1 of the upper semiconductor layer 106, as shown in FIG. 2. For example, the electrode separation pattern 115 may include a portion inserted into a top portion of the buried insulating layer 104.

In example embodiments, the device isolation pattern 112 and the electrode separation pattern 115 may be formed using the same process. In this case, the device isolation pattern 112 and the electrode separation pattern 115 may be formed to have the same depth, as shown in FIG. 19. Furthermore, the device isolation pattern 112 and the electrode separation pattern 115 may be formed of the same material. For example, the device isolation pattern 112 and the electrode separation pattern 115 may be formed of or include at least one of silicon oxide, silicon nitride, or silicon oxynitride.

In other example embodiments, the device isolation pattern 112 and the electrode separation pattern 115 may be formed by different processes. In this case, as described with reference to FIGS. 4 through 7, the device isolation pattern 112 and the electrode separation pattern 115 may be formed to have different depths from each other and be formed to be overlapped with or spaced apart from each other.

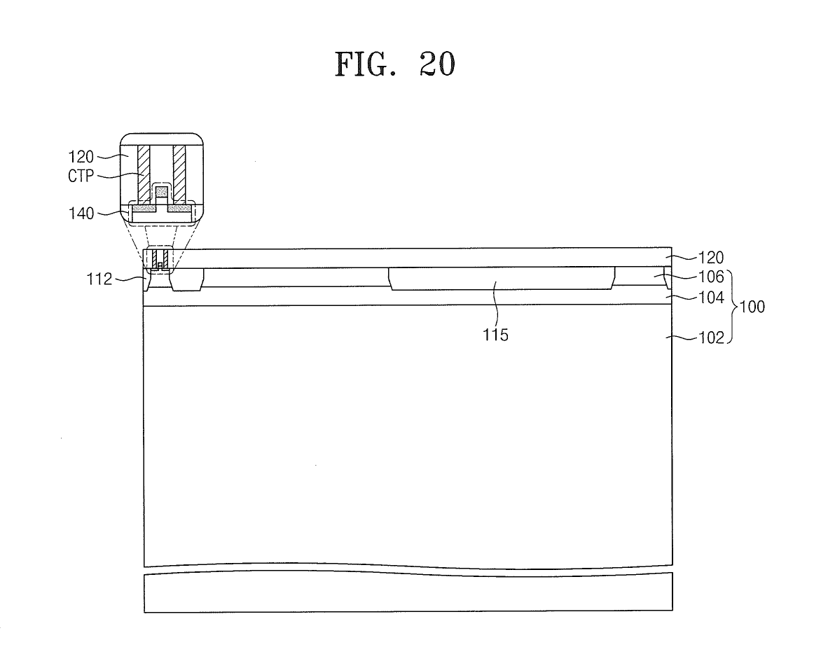

Referring to FIGS. 18 and 20, contact plugs CTP may be formed on the upper semiconductor layer 106 to be connected to the electronic devices 140 and the electronic devices 140 (in Block 2). The electronic devices 140 may be formed on the active regions defined in the upper semiconductor layer 106. In example embodiments, each of the electronic devices 140 may include transistors, each of which includes a gate electrode and source/drain regions at both sides of the gate electrode, but example embodiments of the inventive concepts may not be limited thereto. The formation of the contact plugs CTP may include forming an interlayer insulating layer 120 to cover the electronic devices 140, patterning the interlayer insulating layer 120 to form contact holes exposing the gate electrode and the source/drain regions, and then, forming a conductive layer to fill the contact holes.

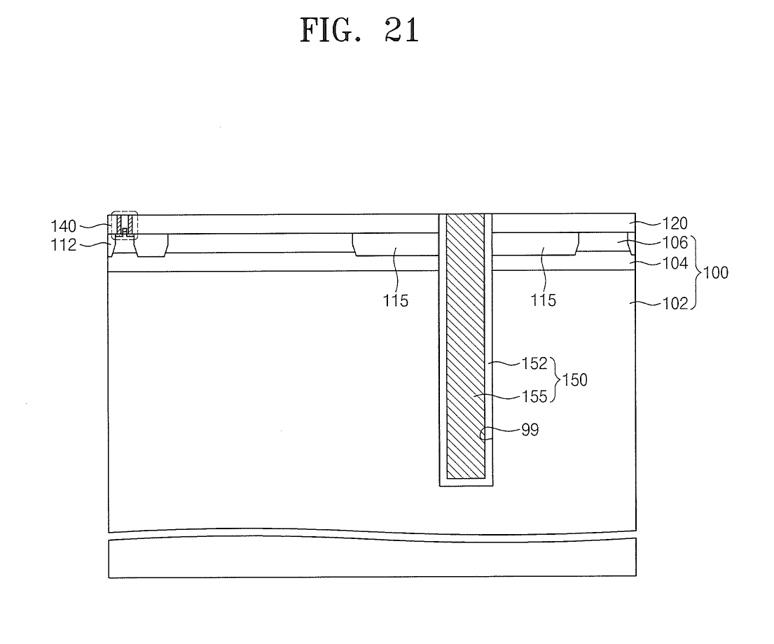

Referring to FIGS. 18 and 21, the vertical electrode structure 150 may be formed to be inserted into the substrate 100. The vertical electrode structure 150 may be formed to penetrate the interlayer insulating layer 120, the upper semiconductor layer 106, and the buried insulating layer 104. For example, the vertical electrode structure 150 may be formed to include a portion that is partially inserted into the lower semiconductor layer 102.

The formation of the vertical electrode structure 150 may include forming the vertical electrode holes 99 to penetrate partially the substrate 100, forming insulating liners 152 to conformally cover inner surfaces of the vertical electrode holes 99, and forming the vertical electrodes 155 to fill the vertical electrode holes 99 provided with the insulating liners 152. Each of the vertical electrode holes 99 or each of the vertical electrodes 155 may be formed to have a width of about several micrometers and a depth of about several tens micrometers.

The vertical electrode holes 99 may be formed using a reactive ion etching (RIE) process, and in this case, charged particles may be produced near the vertical electrode holes 99. In the case where such charged particles are infiltrated into the electronic devices 140, the electronic devices 140 may suffer from deteriorated properties. However, according to example embodiments of the inventive concept, such problems may be reduced/prevented by the buried insulating layer 104 and the electrode separation pattern 115.

In more detail, when viewed in a plan view, the electrode separation pattern 115 may be formed to form/define a perimeter around (e.g., to surround) the vertical electrode structure 150. For example, the electrode separation pattern 115 may be formed to have one of horizontal dispositions, which were exemplarily described with reference to FIGS. 3 through 14. Accordingly, the vertical electrode structure 150 may be spatially and electrically separated from the electronic devices 140. Further, when viewed in a vertical section, the electronic devices 140 may be spatially and electrically separated from the lower semiconductor layer 102 by the buried insulating layer 104. Since the buried insulating layer 104 and the electrode separation pattern 115 reduce/prevent the infiltration of the charged particles in both of vertical and horizontal directions, it is possible to protect/prevent the electronic devices 140 from being deteriorated by the charged particles.

The insulating liners 152 may be formed of or include at least one of silicon oxide, silicon nitride, or silicon oxynitride. The vertical electrodes 155 may be formed using an electroplating or deposition technique, but example embodiments of the inventive concepts may not be limited thereto. For example, the formation of the vertical electrodes 155 may include forming a seed layer to cover inner surfaces of the vertical electrode holes 99 provided with the insulating liners 152, and then, performing an electroplating process, in which the seed layer is used as an electrode. As the result of the electroplating process, the vertical electrode holes 99 with the insulating liners 152 may be filled with a conductive material (for example, copper). Thereafter, the conductive material may be planarized by, for example, a chemical-mechanical polishing process, and thus, top surfaces of the contact plugs CTP may be exposed.

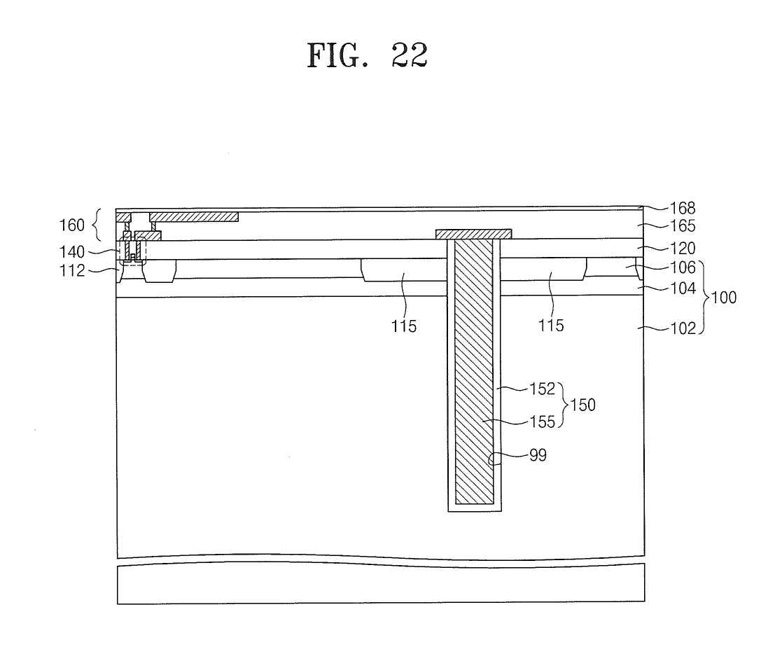

Referring to FIGS. 18 and 22, an interconnection structure 160 and an inter-metal insulating layer 165 supporting the interconnection structure 160 may be provided on the structure with the vertical electrode structure 150 (in Block 4). The interconnection structure 160 may be provided in the form of a multi-layered metal structure including a plurality of metal patterns. Thereafter, an upper protection layer 168 may be formed to cover the interconnection structure 160 and the inter-metal insulating layer 165. The upper protection layer 168 may be formed of silicon oxide, silicon nitride, or polymer (e.g., polyimide), or any combination thereof.

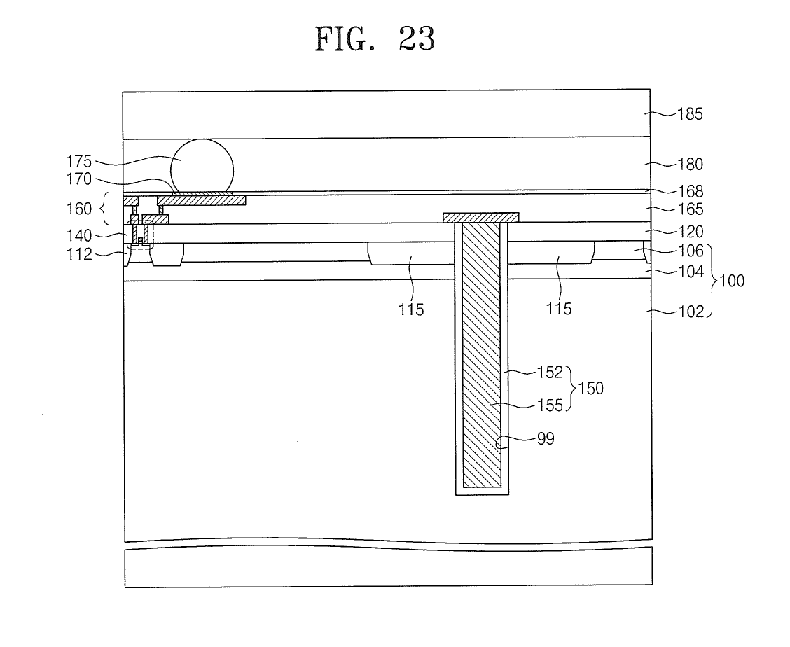

As shown in FIGS. 18 and 23, upper connection terminals 175 may be formed to be coupled to the interconnection structure 160 (in Block 5). An upper under-bump-metallurgy (UBM) 170 may be further formed between the upper connection terminals 175 and the interconnection structure 160. In example embodiments, the upper connection terminals 175 may be provided in the form of C4 bumps or micro bumps. Thereafter, a carrier 185 may be attached to the upper protection layer 168, in which the upper connection terminals 175 are provided, using an adhesive layer 180.

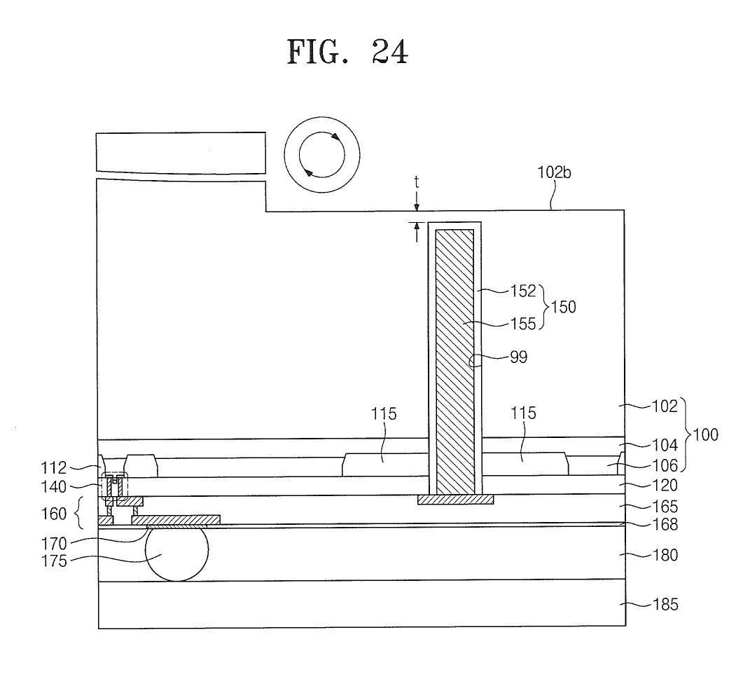

Next, as shown in FIGS. 18 and 24, a back-grinding process may be performed to reduce a thickness of the substrate 100 (in Block 6). The back-grinding process may be performed using a chemical-mechanical polishing process, a grinding process, or any combination thereof. In the case where the vertical electrodes 155 contain copper, the back-grinding process may be performed in such a way that bottom ends of the vertical electrodes 155 are not exposed. For example, the back-grinding process may be performed to remain the lower semiconductor layer 102, for example, of a specific thickness t, on the vertical electrodes 155.

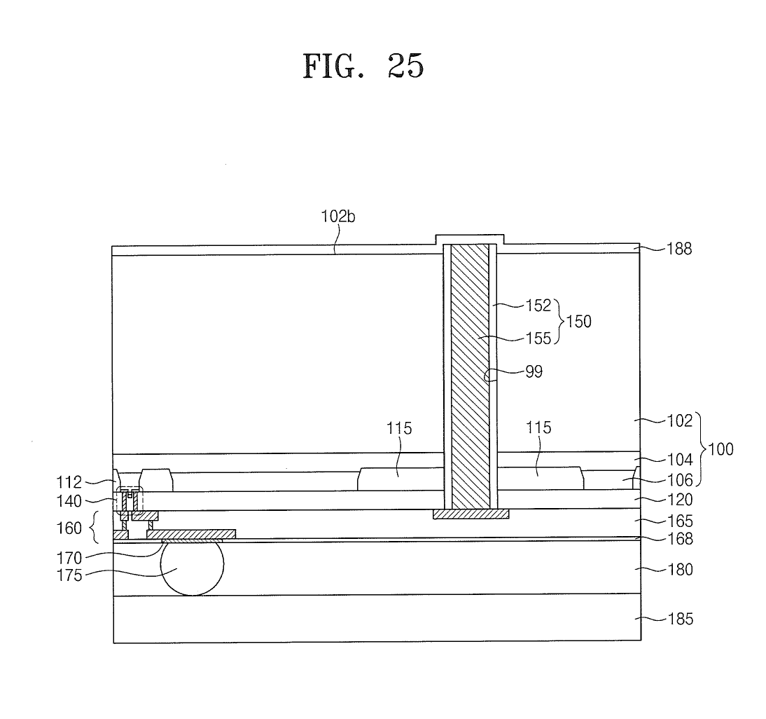

As shown in FIGS. 18 and 25, a back surface 102b of the substrate 100 may be recessed to expose the bottom ends of the vertical electrode structure 150, and then, the lower protection layer 188 may be formed to cover the resulting structure (in Block 7). The recess of the back surface 102b may be performed to etch the lower semiconductor layer 102 and the insulating liner 152 and thereby to expose the bottom ends of the vertical electrodes 155. In example embodiments, the recess of the back surface 102b may be performed using a wet or dry etching process. The lower protection layer 188 may be formed of silicon oxide, silicon nitride, or polymer (e.g., polyimide), or any combination thereof.

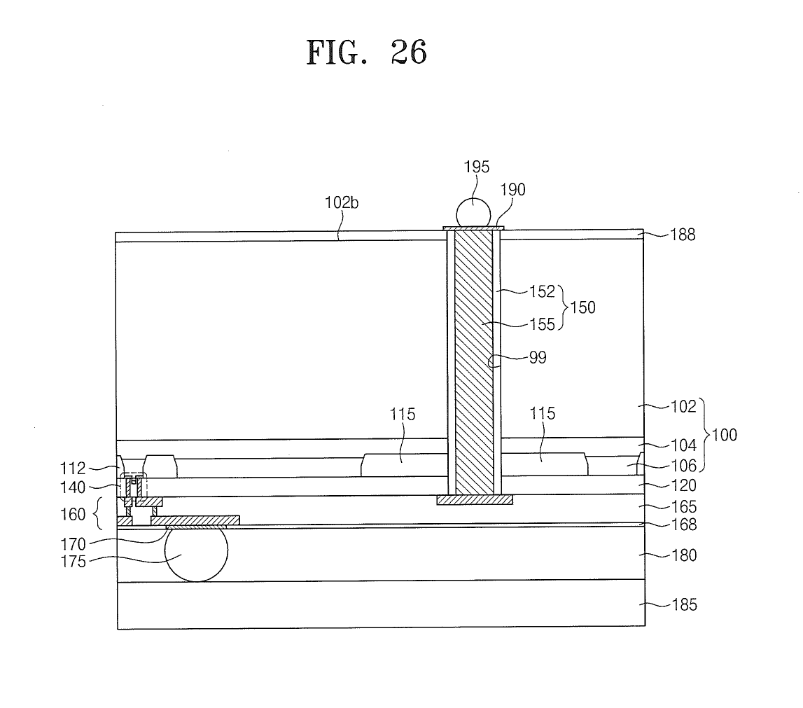

Referring to FIGS. 18 and 26, the lower protection layer 188 may be etched to expose the bottom ends of the vertical electrodes 155, and then, lower connection terminals 195 may be formed on the exposed bottom ends of the vertical electrodes 155 (in Block 8). The lower UBM 190 may be further formed between the lower connection terminals 195 and the vertical electrodes 155. In example embodiments, the lower connection terminals 195 may be provided in the form of C4 bumps or micro bumps.

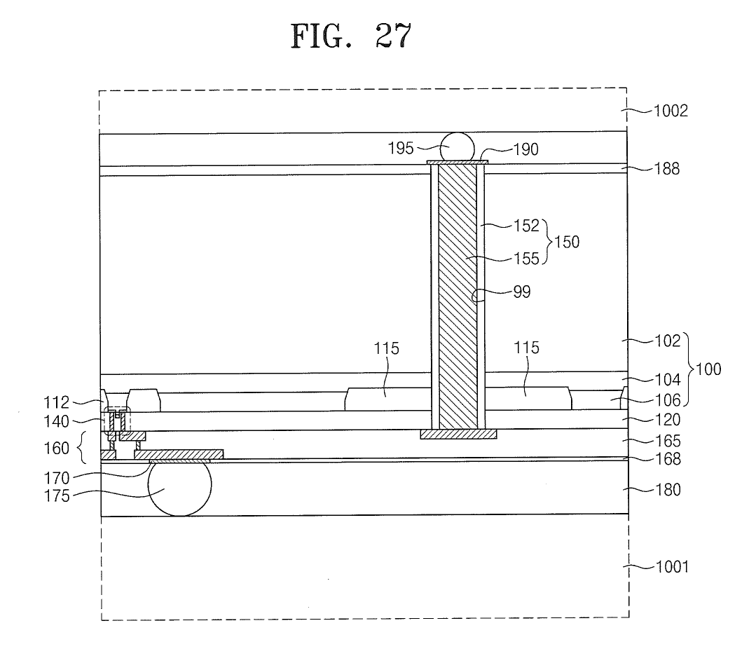

As shown in FIGS. 18 and 27, the semiconductor chip prepared by the afore-described processes may be mounted on a lower structure 1001 (in Block 9). The lower structure 1001 may be the package substrate PS, the interposer ITP, or another semiconductor chip of homogeneous or heterogeneous type. Furthermore, an upper structure 1002 may be further mounted on the semiconductor chip prepared by the afore-described processes. The upper structure 1002 may be a third semiconductor chip of homogeneous or heterogeneous type.

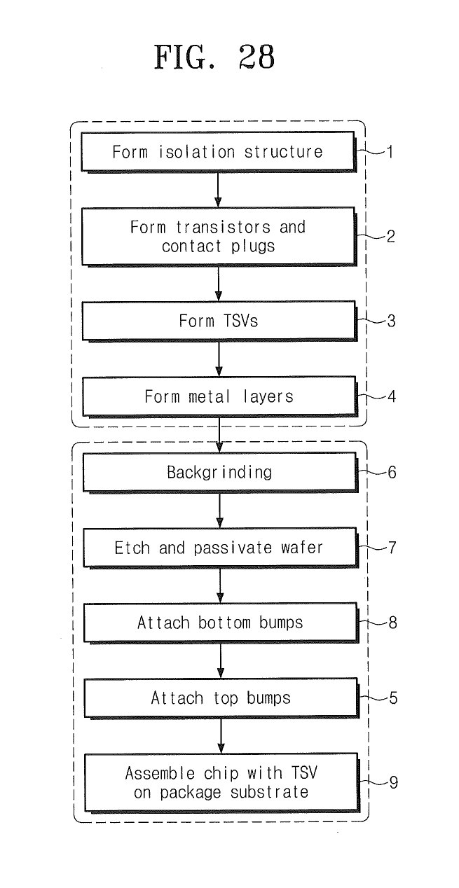

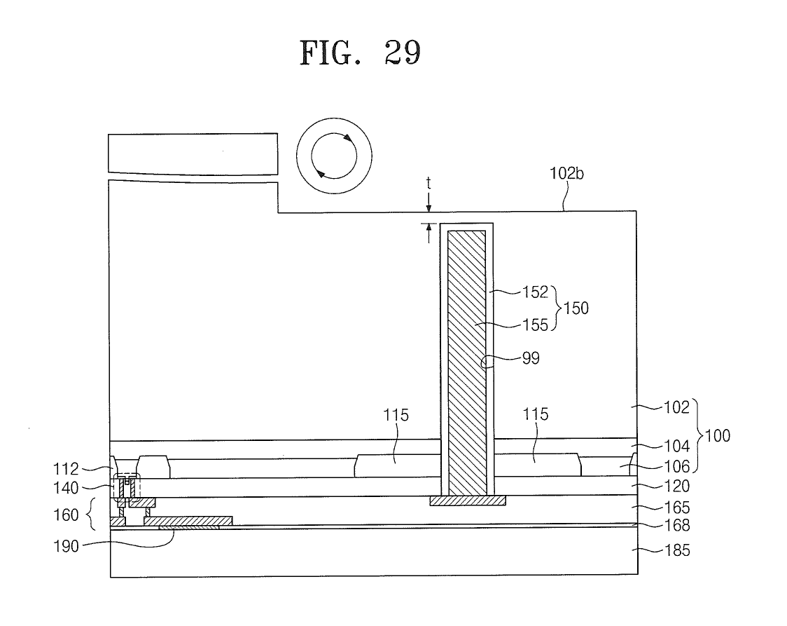

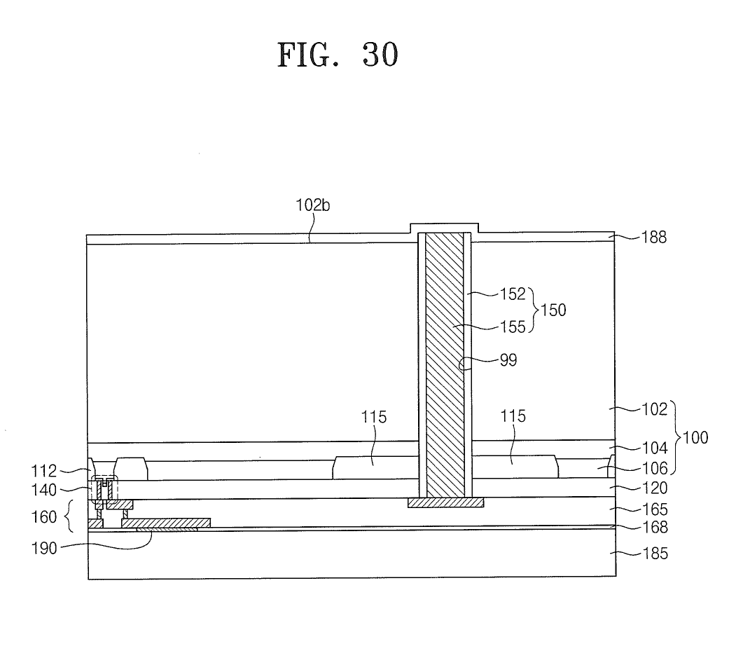

The fabricating method described with reference to FIGS. 18 through 27 may be an example of a face-to-back via-middle process according to example embodiments of the inventive concept. In other words, in the present embodiment, the vertical electrode structure 150 may be formed between steps of forming the contact plugs CTP and the interconnection structure 160, and the semiconductor chip may be attached to the lower structure 1001 in such a way that the electronic devices 140 are inverted. Hereinafter, an example of a face-to-face via-middle process, to which the inventive concept can be applied, will be briefly described with reference to FIGS. 28 through 33. FIG. 28 is a flow chart illustrating a method of fabricating a semiconductor device according to other example embodiments of the inventive concept, and FIGS. 29 through 33 are sectional views illustrating a method of fabricating a semiconductor device according to other example embodiments of the inventive concept. For concise description, the elements and features of this example that are similar to those previously shown and described with reference to FIGS. 18 through 27 will not be described in much further detail.

Referring to FIG. 28, the vertical electrode structure 150 may be formed between steps of forming the contact plugs CTP and the interconnection structure 160. In other words, the vertical electrode structure 150 may be formed before the back-grinding process (Block 6). Accordingly, the semiconductor device according to the present embodiment may be fabricated in a via-middle manner.

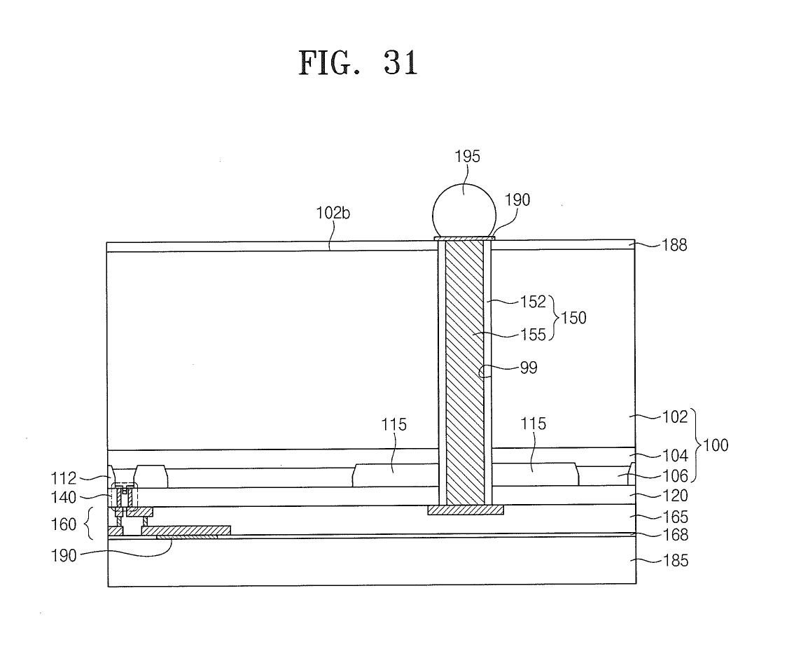

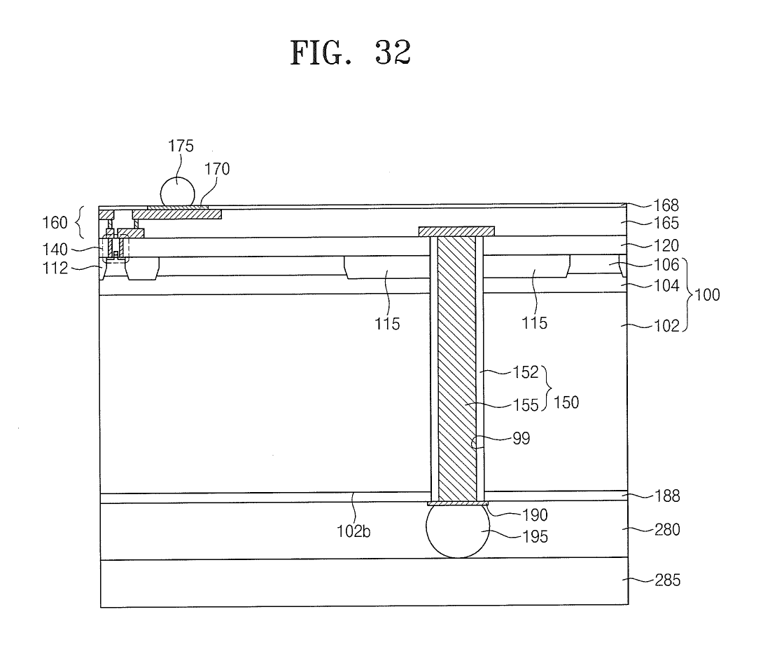

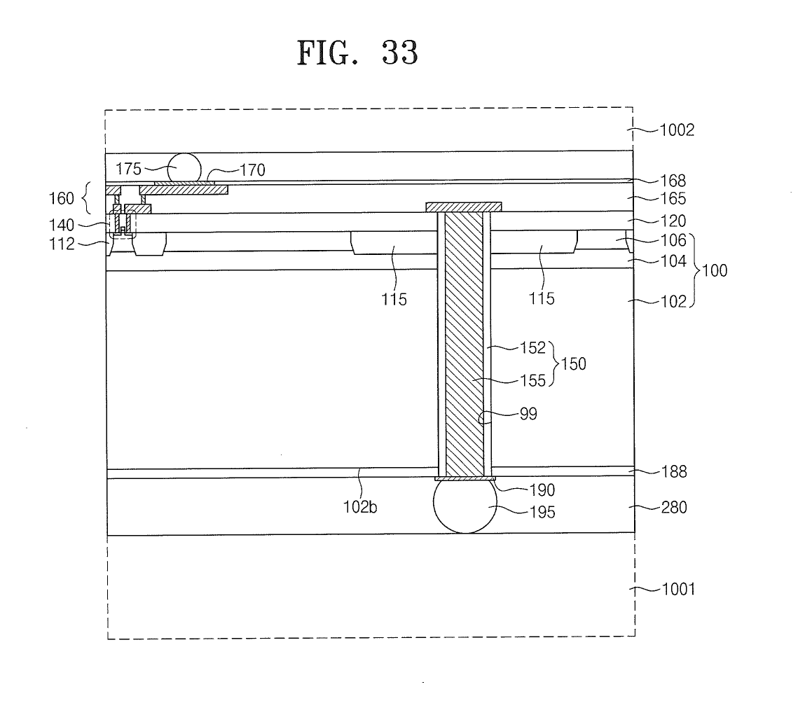

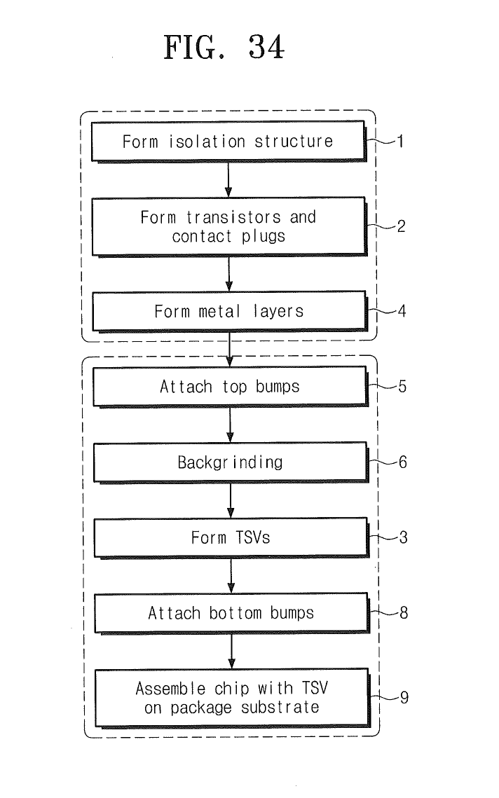

Further, as shown in FIGS. 28 through 31, the back-grinding process (Block 6) and the process (Block 7) of recessing the back surface 102b and forming the lower protection layer 188 may be sequentially performed before the formation (Block 8) of the lower connection terminals 195. In the present embodiment, as shown in FIGS. 31 and 32, the upper connection terminals 175 may be formed after the formation of the lower connection terminals 195. A carrier 285 may be attached to the lower protection layer 188 using an adhesive layer 280. Accordingly, as shown in FIG. 33, the semiconductor chip may be mounted on the lower structure 1001 in a face-to-face manner.

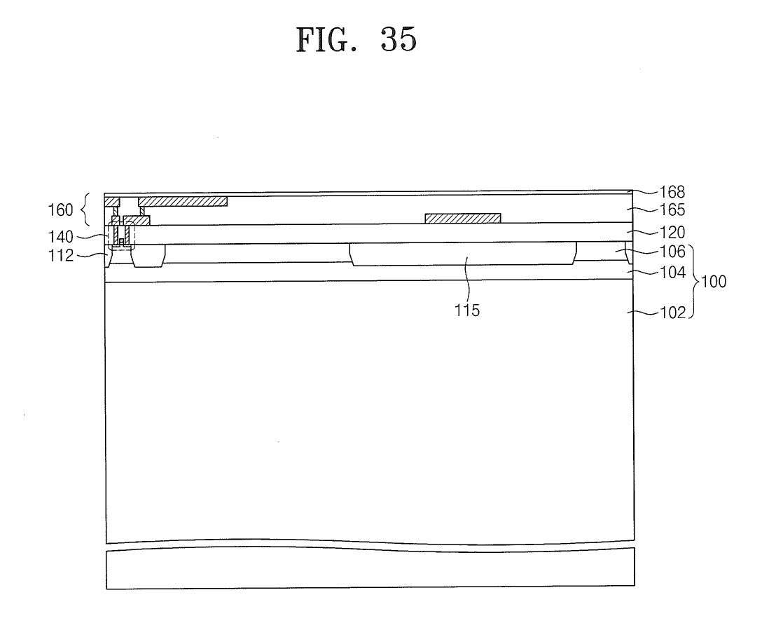

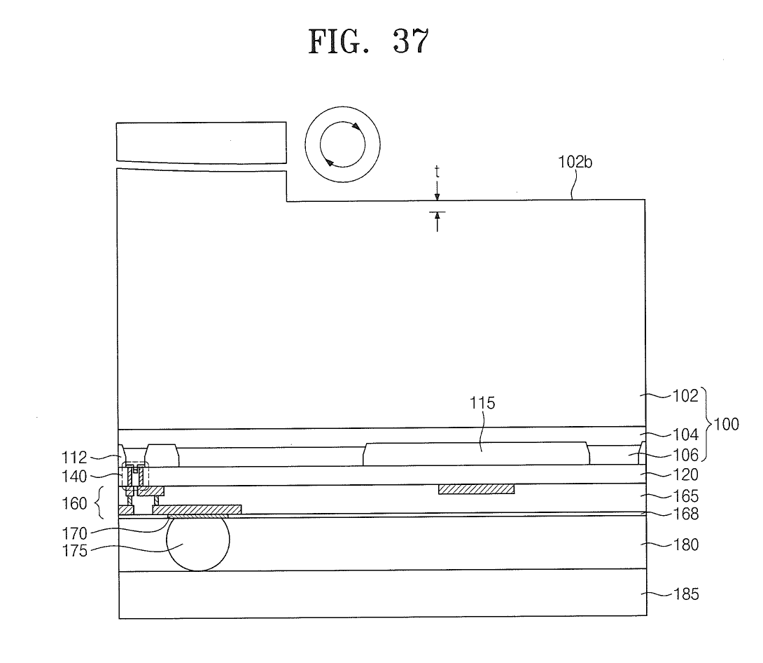

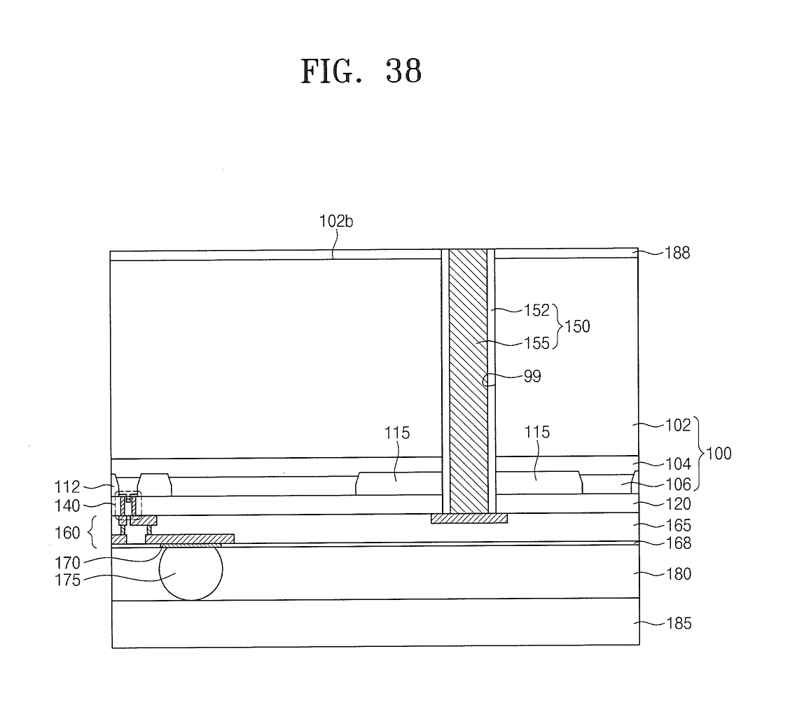

Hereinafter, an example of a face-to-back via-last process, to which the inventive concept can be applied, will be briefly described with reference to FIGS. 34 through 38. FIG. 34 is a flow chart illustrating a method of fabricating a semiconductor device according to still other example embodiments of the inventive concept, and FIGS. 35 through 38 are sectional views illustrating a method of fabricating a semiconductor device according to still other example embodiments of the inventive concept. For concise description, the elements and features of this example that are similar to those previously shown and described with reference to FIGS. 18 through 27 will not be described in much further detail.

Referring to FIG. 34, the vertical electrode structure 150 may be formed after the formation of the interconnection structure 160 (for example, after the back-grinding process (Block 6)). Since the vertical electrode structure 150 is formed after a front-end process of the semiconductor chip, the semiconductor device according to the present embodiment may be fabricated in a via-last manner.

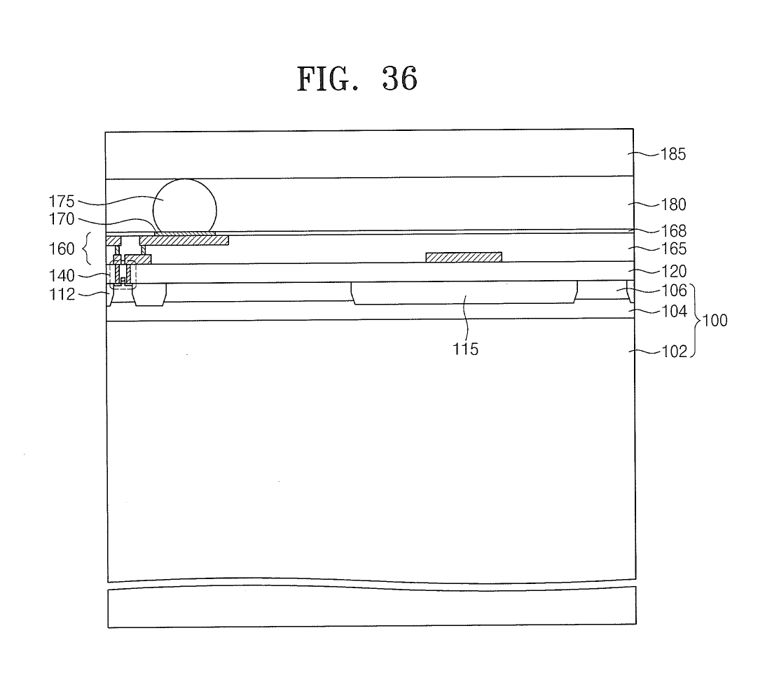

In detail, as shown in FIG. 35, the interconnection structure 160 and the interlayer insulating layer 120 may be formed on the substrate 100, in which the vertical electrode structure 150 is not provided. Next, as shown in FIGS. 36 through 38, the formation (Block 5) of the upper connection terminals 175 and the back-grinding process (Block 6) may be sequentially performed before formation (Block 3) of the vertical electrode structure 150. Processes following the formation (Block 3) of the vertical electrode structure 150 may be performed in the same manner as those in the previous embodiments described with reference to FIGS. 26 and 27. Accordingly, as shown in FIG. 27, the semiconductor chip may be mounted on the lower structure 1001 in a face-to-back manner.

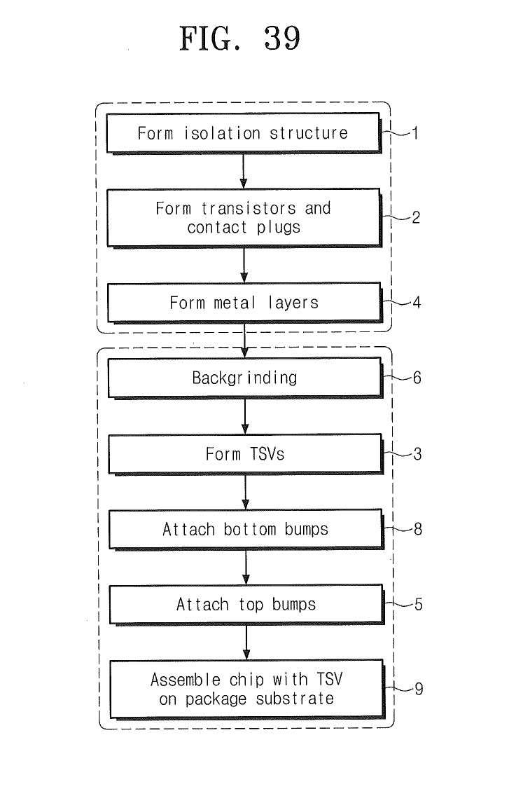

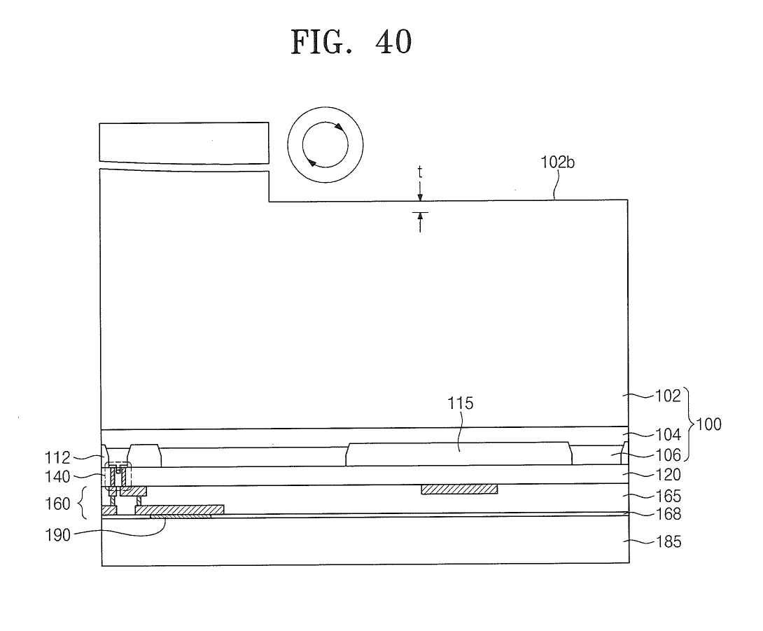

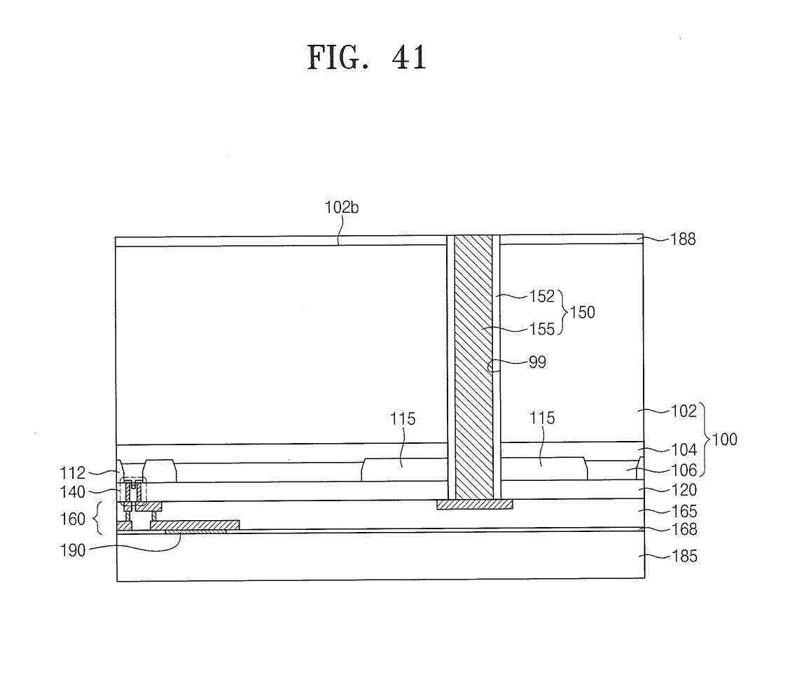

Hereinafter, an example of a face-to-face via-last process, to which the inventive concept can be applied, will be briefly described with reference to FIGS. 39 through 42, FIG. 39 is a flow chart illustrating a method of fabricating a semiconductor device according to even other example embodiments of the inventive concept, and FIGS. 40 through 42 are sectional views illustrating a method of fabricating a semiconductor device according to even other example embodiments of the inventive concept. For concise description, the elements and features of this example that are similar to those previously shown and described with reference to FIGS. 18 through 27 will not be described in much further detail.

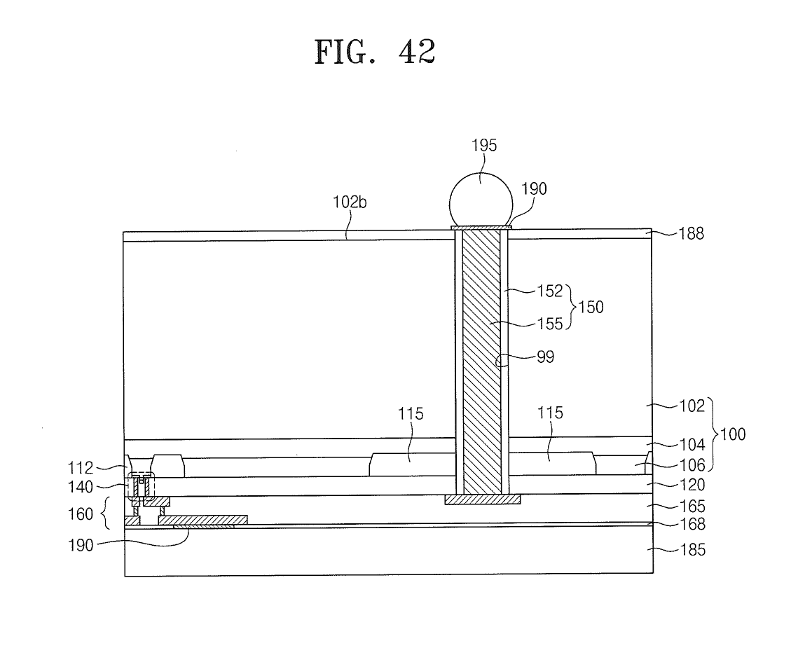

Referring to FIGS. 39 through 42, the back-grinding process (Block 6), the formation (Block 3) of the vertical electrode structure 150, and the formation (Block 8) of the lower connection terminals 195 may be sequentially performed after the formation (Block 4) of the interconnection structure 160. As shown in FIG. 42, processes following the formation (Block 8) of the lower connection terminals 195 may be performed in the same manner as those in the previous embodiments described with reference to FIGS. 32 and 33. Accordingly, as shown in FIG. 33, the semiconductor chip may be mounted on the lower structure 1001 in a face-to-face manner.

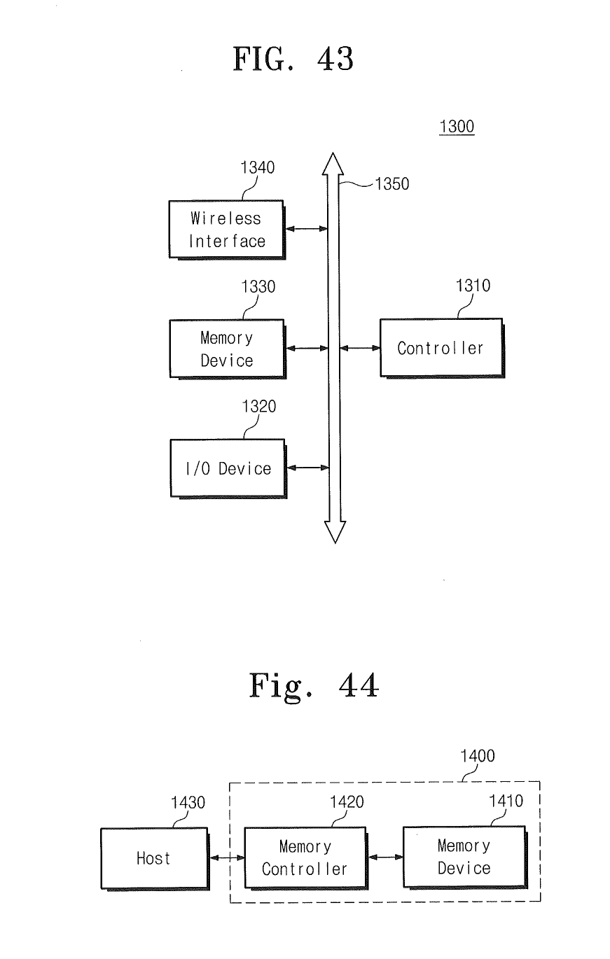

FIGS. 43 and 44 are block diagrams schematically illustrating electronic devices including a semiconductor device according to example embodiments of the inventive concept.

Referring to FIG. 43, an electronic device 1300 including a semiconductor device according to example embodiments of the inventive concept may be used in one of a personal digital assistant (PDA), a laptop computer, a mobile computer, a web tablet, a wireless phone, a cell phone, a digital music player, a wired or wireless electronic device, or a complex electronic device including a combination of such functionalities. The electronic device 1300 may include a controller 1310, an input/output device (s) 1320 (for example, a keypad, a keyboard, or a display), a memory 1330, and/or a wireless interface 1340 that are connected/coupled to each other through a bus 1350. The controller 1310 may include, for example, at least one microprocessor, a digital signal process, a microcontroller, etc. The memory 1330 may be configured to store a command code to be used by the controller 1310 and/or user data. The memory 1330 and/or the controller 1310 may include a semiconductor device according to example embodiments of inventive concepts. The electronic device 1300 may use a wireless interface 1340 configured to transmit data to and/or receive data from a wireless communication network using a RF (radio frequency) signal. The wireless interface 1340 may include, for example, an antenna, a wireless transceiver, etc. The electronic system 1300 may be used in a communication interface protocol of a communication system according to a standard such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, etc.

Referring to FIG. 44, a memory system including a semiconductor device according to example embodiments of inventive concepts will be described. The memory system 1400 may include a memory device 1410 for storing relatively large quantities of data and a memory controller 1420. The memory controller 1420 controls the memory device 1410 so as to read data stored in the memory device 1410 and/or to write data into the memory device 1410 in response to a read/write request of a host 1430. The memory controller 1420 may include an address mapping table for mapping an address provided from the host 1430 (e.g., a mobile device or a computer system) into a physical address of the memory device 1410. The memory device 1410 and/or the memory controller 1410 may be a semiconductor device according to example embodiments of inventive concepts.

According to example embodiments of the inventive concept, provided is a semiconductor device including a buried insulating layer and an electrode separation pattern. The electrode separation pattern makes it possible to separate vertical electrodes (for example, through-silicon via) penetrating a substrate from electronic devices (for example, integrated circuit) integrated on an upper semiconductor layer, in a horizontal direction. Because the buried insulating layer separates a lower semiconductor layer vertically from the upper semiconductor layer, it is possible to impede/prevent electric pathways from being formed between the electronic devices and the vertical electrodes, in a vertical direction. Accordingly, it is possible to protect/prevent internal circuits of a semiconductor chip from being damaged in or by a process of forming through-silicon vias.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
a substrate including a lower semiconductor layer, a buried insulating layer, and an upper semiconductor layer;
electronic devices on the upper semiconductor layer;
a vertical electrode structure including a vertical electrode penetrating the substrate; and
an electrode separation pattern defining a perimeter around the vertical electrode structure in a plan view and penetrating the upper semiconductor layer to directly contact the buried insulating layer.

2. The device of claim 1, wherein the electrode separation pattern has a first thickness that is thicker than a second thickness of the upper semiconductor layer.

3. The device of claim 1, wherein the electronic devices are separated from both of the lower semiconductor layer and the vertical electrode structure by the buried insulating layer and the electrode separation pattern.

4. The device of claim 1, further comprising a device isolation pattern defining active regions, on which the electronic devices are provided.

5. The device of claim 4, wherein the device isolation pattern penetrates the upper semiconductor layer and directly contacts the buried insulating layer.

6. The device of claim 4, wherein the device isolation pattern has a first thickness that is thinner than a second thickness of the upper semiconductor layer.

7. The device of claim 6, wherein the electrode separation pattern is spaced apart from the device isolation pattern.

8. The device of claim 6,
wherein the device isolation pattern is around the vertical electrode structure, and
wherein the electrode separation pattern penetrates the device isolation pattern.

9. The device of claim 1,
wherein the electrode separation pattern comprises one electrode separation pattern among a plurality of electrode separation patterns penetrating the upper semiconductor layer,
wherein the vertical electrode comprises one vertical electrode among a plurality of vertical electrodes, and
wherein each of the plurality of electrode separation patterns surrounds a corresponding one of the plurality of vertical electrodes.

10. The device of claim 1,
wherein the vertical electrode comprises one vertical electrode among a plurality of vertical electrodes,
wherein the plurality of vertical electrodes are in a bump region of the substrate, and
wherein the electrode separation pattern comprises at least one closed-loop-shaped pattern surrounding the bump region.

11. The device of claim 1, wherein the electrode separation pattern comprises at least one of a silicon oxide layer, a silicon nitride layer, or a silicon oxynitride layer.

12. The device of claim 1, further comprising an interlayer insulating layer on the upper semiconductor layer, wherein the electrode separation pattern is between the buried insulating layer and the interlayer insulating layer.

13. A semiconductor package comprising a package substrate and a plurality of semiconductor chips on the package substrate, wherein at least one of the plurality of semiconductor chips is a chip of a first type, the chip of the first type comprising:
a substrate including a lower semiconductor layer, a buried insulating layer, and an upper semiconductor layer;
electronic devices on the upper semiconductor layer;
a vertical electrode structure including a vertical electrode penetrating the substrate; and
an electrode separation pattern defining a perimeter around the vertical electrode structure in a plan view and directly contacting the buried insulating layer through the upper semiconductor layer.

14. The package of claim 13,
wherein the plurality of semiconductor chips comprise a plurality of memory chips that are sequentially stacked on the package substrate to form a memory-chip stack structure, and
wherein at least one of the memory chips is the chip of the first type.

15. The package of claim 14,
wherein the plurality of semiconductor chips further comprise at least one logic chip between the plurality of memory chips and the package substrate or on the package substrate with the plurality of memory chips interposed therebetween, and
wherein the at least one logic chip is the chip of the first type.

16. The package of claim 13,
wherein the vertical electrode comprises one vertical electrode among a plurality of vertical electrodes,
wherein the plurality of vertical electrodes are in a bump region of the substrate, and
wherein the electrode separation pattern comprises at least one closed-loop-shaped pattern surrounding the bump region.

17. The package of claim 13,
wherein the electrode separation pattern comprises one electrode separation pattern among a plurality of electrode separation patterns penetrating the upper semiconductor layer,
wherein the vertical electrode comprises one vertical electrode among a plurality of vertical electrodes,
wherein the plurality of vertical electrodes are in a bump region of the substrate, and
wherein each of the plurality of electrode separation patterns surrounds a corresponding one of the plurality of vertical electrodes.

18. The package of claim 13,
wherein the chip of the first type further comprises a device isolation pattern defining active regions, on which the electronic devices are provided,
wherein the electrode separation pattern has a first thickness that is thicker than a second thickness of the upper semiconductor layer, and
wherein the device isolation pattern has a third thickness that is substantially equal to or thinner than the first thickness of the electrode separation pattern.

19. A semiconductor device, comprising:
a substrate including a lower semiconductor layer, a buried insulating layer, and an upper semiconductor layer;
a device isolation pattern in the upper semiconductor layer and defining active regions;
electronic devices on the active regions;
vertical electrodes penetrating the substrate; and
at least one electrode separation pattern surrounding the vertical electrodes in a plan view and directly contacting the buried insulating layer through the upper semiconductor layer,
wherein a first thickness of the at least one electrode separation pattern is thicker than a second thickness of the upper semiconductor layer, and
wherein a third thickness of the device isolation pattern is substantially equal to or thinner than that the first thickness of the at least one electrode separation pattern.

20. The device of claim 19, wherein the electronic devices are electrically isolated from all of the vertical electrodes by the buried insulating layer and the at least one electrode separation pattern.
